(19) United States
(12) Patent Application Publication
(10) Pub. No.: US 2011/0156241 A1
(43) Pub. Date: Jun. 30, 2011

(54) PACKAGE SUBSTRATE AND METHOD OF FABRICATING THE SAME

(76) Inventors: Ju Pyo HONG, Gyunggi-do (KR); Young Do Kweon, Seoul (KR); Jin Gu Kim, Gyunggi-do (KR); Seung Wook Park, Gyunggi-do (KR); Hee Kon Lee, Gyunggi-do (KR)

(21) Appl. No.: 12/712,044

(22) Filed: Feb. 24, 2010

(30) Foreign Application Priority Data
Dec. 28, 2009 (KR) 10-2009-0131869

(51) Int. Cl. H01L 23/498; H01L 21/60

(52) U.S. Cl. 257/693; 438/124; 257/E23.068; 257/E21.506

(57) ABSTRACT

Disclosed herein are a package substrate and a method of fabricating the same. The package substrate includes a base part that includes a chip, a mold part surrounding the chip, and a connection unit formed inside the mold part to connect the chip to a terminal part formed on the outer surface of the mold part, and a buildup layer that is formed on one surface of the base part on which the terminal part is formed, including the side surfaces of the base part, but includes a circuit layer connected to the terminal part, thereby making it possible to minimize stress applied to chips during a buildup process and easily replace malfunctioning chips.

### CROSS REFERENCE TO RELATED APPLICATION

This application claims the benefit of Korean Patent Application No. 10-2009-0131869, filed on Dec. 28, 2009, entitled “A Package Substrate and a Method of Fabricating the Same”, which is hereby incorporated by reference in its entirety into this application.

### BACKGROUND OF THE INVENTION

1. Technical Field

The present invention relates to a package substrate and a method of fabricating the same.

2. Description of the Related Art

Several tens to several hundreds of chips may be generally formed per a sheet of wafer. However, although the respective chips are supplied with electricity from the outside, they cannot supply or receive electrical signals by themselves. Further, the chips are easily damaged by external impacts since they have fine circuits. Therefore, a packaging technology that electrically connects the chips and protects the chips from the external impact has been gradually developed.

Recently, with the development of electronic industry, high-performance and miniaturization of electronic components have been gradually requested. In particular, a market trend of a personal portable device has become light and small and thus a circuit board has become slim. While efforts are continuously made to serve many functions to limited areas, a development of a component built-in substrate has been spotlighted as a next generation multi-functional/small package technology.

Meanwhile, in the semiconductor industry, a packaging technology for an integrated circuit has been continuously developed in order to meet the demands for miniaturization and packaging reliability. For example, the demand for the miniaturization has accelerated the technical development of a package, such that the size of the integrated circuit is close to a chip size. In addition, the demand for the package reliability has emphasized the importance of the packaging technology that can improve the efficiency of the package work and mechanical/electrical reliability after being packaged.

FIG. 1 is a cross-sectional view of a package substrate according to one embodiment of the related art. Hereinafter, the package substrate 10 of the related art will be described with reference to FIG. 1.

As shown in FIG. 1, the package substrate 10 of the related art includes a base substrate 11, a chip 12, and a buildup layer 20.

More specifically, a cavity 15 is formed on the base substrate 11, the chip 12 is bonded to the cavity 15 by an adhesive layer 13 to be mounted, and the buildup layer 20 including a plurality of circuit layers 22 and insulating layers 23 are formed on the base substrate 11 mounted with the chip 12. At this time, a via 21 that electrically connects a circuit layer (not shown) of the chip 12 or the base substrate 11 to the circuit layer 22 of the buildup layer 20, and a solder ball 24 that connects the circuit layer 22 to an external device may further be formed on the buildup layer 20.

However, in the case of the package substrate 10 according to one embodiment of the related art, stress is applied to the chip 12 during a stack process of the buildup layer 20 to cause defects of the chip 12, thereby increasing process costs and process time.

In order to solve such problems, there has been study of a package substrate that forms a multi-chip stack structure by a package substrate of which function test had been already completed.

FIG. 2 is a cross-sectional view of a package substrate 30 according to another embodiment of the related art. Hereinafter, the package substrate 30 of the related art will be described with reference to FIG. 2.

As shown in FIG. 2, the package substrate 30 of the related art is formed by stacking a first package substrate and a second package substrate.

More specifically, a first chip 42 is fixed and positioned to a first substrate 40 by a first adhesive layer 43, and the circuit layer 41 of the first substrate 40 is connected to the first chip 42 by a first wire 44. Then, a first mold 45 is formed on the first chip 42, thereby completing the first package substrate.

Moreover, a second chip 52 is fixed onto a second substrate 50 by a second adhesive layer 53, and the circuit layer 51 and the second chip 52 of the second substrate 50 are connected to each other by a second wire 54. Then, a second mold 55 is formed on the second chip 52, thereby completing the second package substrate.

Thereafter, the second package substrate is stacked on the first package substrate but the first package substrate and the second package substrate are fixed by interposing a third adhesive layer 63 therebetween, and the circuit layer 41 of the first substrate 40 is connected to the circuit layer 51 of the second substrate 50 by a third wire 61 and then a third mold 60 that covers both the first package substrate and the second package substrate is formed.

However, in the case of the package substrate 30 according to another embodiment of the related art, a problem arises in that the third wire 61, the first substrate 40 or the second substrate 50 is directly damaged when the third mold 60 is removed in order to replace malfunctioning chips. Therefore, there has been a problem in that the chip replacement is not easy.

### SUMMARY OF THE INVENTION

The present invention has been made in an effort to provide a package substrate that minimizes stress applied to chips during a buildup process, and a method of fabricating the same.

Another object of the present invention is to provide a package substrate that can easily replace chips when defects occur in the chips, and a method of fabricating the same.

A package substrate according to an embodiment of the present invention includes: a base part that includes a chip, a mold part surrounding the chip, and a connection unit formed inside the mold part to connect the chip to a terminal part formed on the outer surface of the mold part; and a buildup layer that is formed on one surface of the base part on which the terminal part is formed, including the side surfaces of the base part, includes a circuit layer connected to the terminal part.

Herein, the package substrate may further include a base substrate formed on the other surface of the base part.

Further, the package substrate may further include a solder ball connected to the outermost circuit layer of the circuit layers of the buildup layer.

Further, the package substrate may further include an adhesive layer formed between the base part and the base substrate.

Further, the buildup layer may include insulating layers made of polyimide.

Further, the insulating layers of each layer of the buildup layer may have different glass transition temperature.

Further, the base substrate may be a metal substrate or an anodizing substrate.

Further, the connection unit may be a bump or a wire.

The package substrate may further include a radiation fin of which one side is connected to the base part and the other side is exposed to the base substrate.

The package substrate may include an open part formed in the base substrate, wherein the base part is exposed to the outside through the open part.

Herein, the exposed surface of the base part and the surface of the base substrate exposed to the outside may have the same plane.

A method of fabricating a package substrate according to an embodiment of the present invention includes: (A) positioning a base part that includes a chip, a mold part surrounding the chip, and a connection unit formed inside the mold part to connect the chip to a terminal part formed on the outer surface of the mold part, on a base substrate; and (B) stacking a buildup layer by forming an insulating layer on the base substrate, including the side surfaces of the base part, and forming a circuit layer connected to the terminal part.

At this time, the method of fabricating the package substrate may further include: (C) forming a solder ball that is connected to an outermost circuit layer of the circuit layers of the buildup layer.

Further, at step (A), when the base part is positioned on the base substrate, an adhesive layer may be interposed between the base part and the base substrate.

Further, at step (A), the base substrate may be a metal substrate or an anodizing substrate.

Further, at step (B), the insulating layer of the buildup layer may be made of polyimide.

Further, at step (B), the insulating layers of each layer of the buildup layer may have different glass transition temperature.

Further, at step (A), the connection unit may be a bump or a wire.

The method of fabricating the package substrate may further include: (C) forming a radiation fin that connects the base part to the outside of the base substrate by penetrating through the base substrate.

In the method of fabricating the package substrate, the step (A) may include: (A1) preparing a base part by forming a connection unit connected to the chip, a mold part surrounding the chip, and a terminal part connected to the connection unit on the outer surface of the mold part; (A2) forming an open part in a base substrate; and (A3) positioning the base part in the open part.

### BRIEF DESCRIPTION OF THE DRAWINGS

FIG. 1 is a cross-sectional view of a package substrate according to one embodiment of the related art;

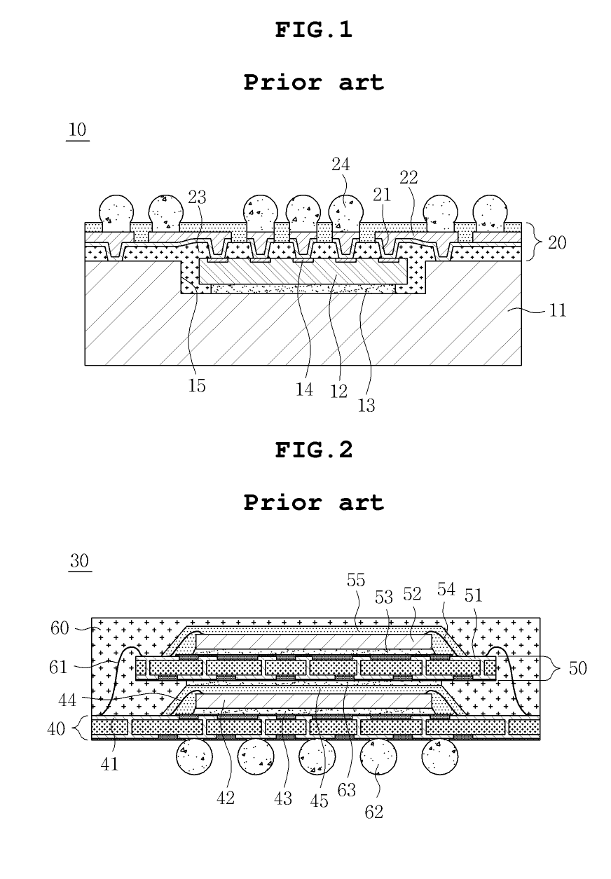

FIG. 2 is a cross-sectional view of a package substrate according to another embodiment of the related art;

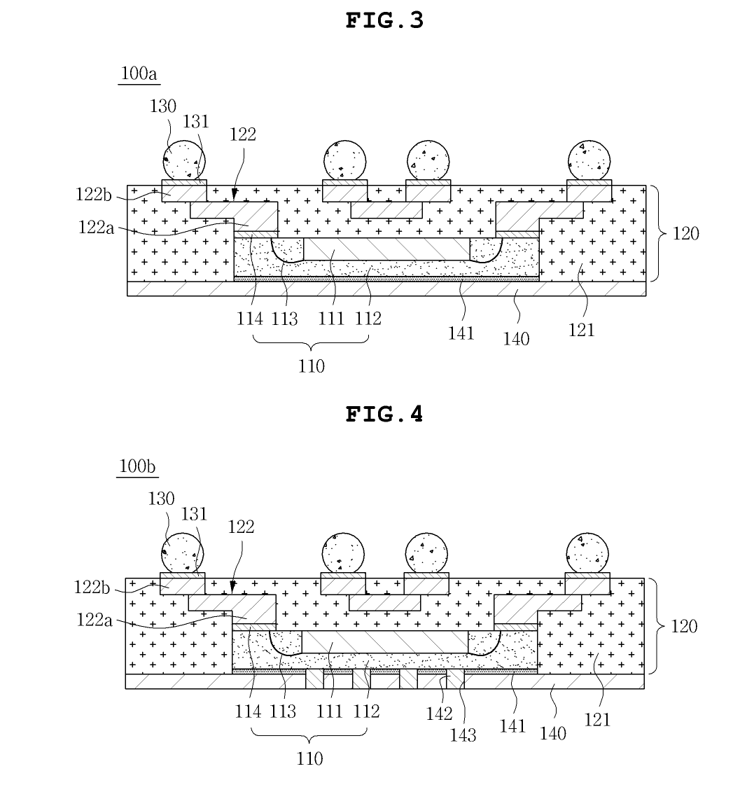

FIG. 3 is a cross-sectional view of a package substrate according to a preferred first embodiment of the present invention;

FIG. 4 is a cross-sectional view of a package substrate according to a preferred second embodiment of the present invention;

FIG. 5 is a cross-sectional view of a package substrate according to a preferred third embodiment of the present invention;

FIGS. 6 to 9 are process cross-sectional views explaining a method of fabricating a package substrate of FIG. 3;

FIGS. 10 to 14 are process cross-sectional views explaining a method of fabricating a package substrate of FIG. 4; and

FIGS. 15 to 18 are process cross-sectional views explaining a method of fabricating a package substrate of FIG. 5.

### DESCRIPTION OF THE PREFERRED EMBODIMENTS

Various features and advantages of the present invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Terms used in the specification, ‘first’, ‘second’, etc. can be used to describe various components, but the components are not to be construed as being limited to the terms. The terms are only used to differentiate one component from other components. Further, in describing the present invention, a detailed description of related known functions or configurations will be omitted so as not to obscure the subject of the present invention. Further, when it is determined that the detailed description of the known art related to the present invention may obscure the gist of the present invention, the detailed description will be omitted.

Hereinafter, the preferred embodiments of the present invention will be described in detail with reference to the accompanying drawings.

<Structure of Package Substrate>

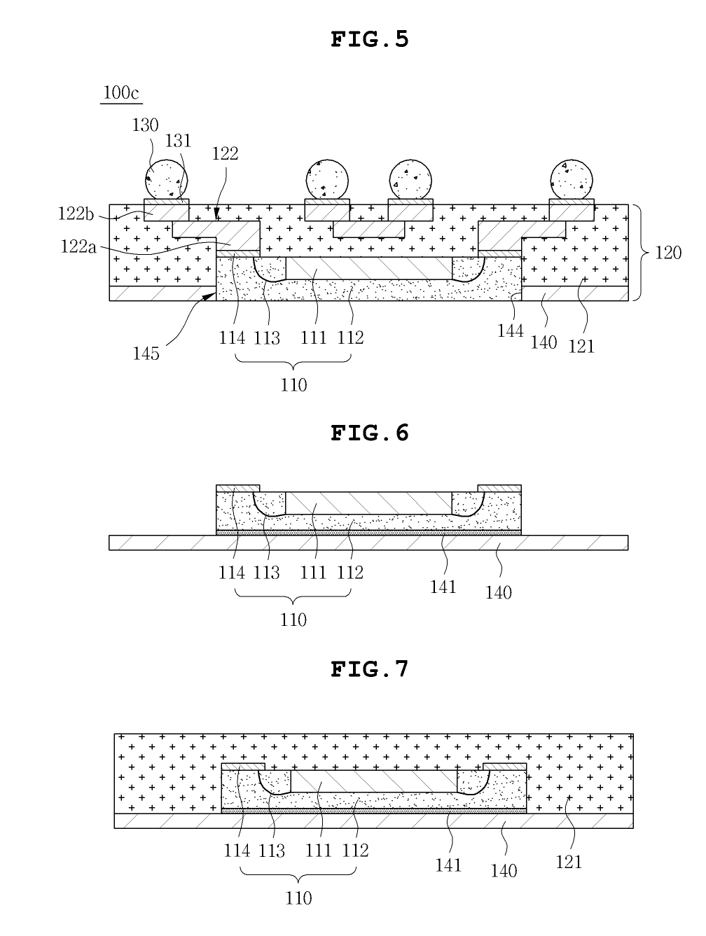

FIG. 3 is a cross-sectional view of a package substrate 100a according to a preferred first embodiment of the present invention. Hereinafter, the package substrate 100a according to the first embodiment will be described with reference to FIG. 3.

As shown in FIG. 3, the package substrate 100a according to the first embodiment includes a base part 110 that is formed on a base substrate 140 and a buildup layer 120 that is formed on the base part 110, including the side surfaces of the base part 110.

The base part 110, which is a member including a chip 111, a mold part 112, a connection unit 113, and a terminal part 114, can protect the chip 111 from the outside.

Herein, the mold part 112, which is a member protecting the outer surface of the chip 111, is formed to have a structure that surrounds the chip 111. The mold part 112 may, for example, be made of epoxy molding compound (EMC). Moreover, a terminal part 114 is formed on the outer surface of the mold part 112 and the terminal part 114 is connected to a circuit layer 122 of a buildup layer 120 to be described hereinafter, making it possible to electrically connect the chip 111 to the outside of the package substrate 100a. At this time, the terminal part 114 may, for example, be made of conductive metals such as gold, silver, copper, nickel, etc.

Further, the connection unit 113, which is a member electrically connecting the chip 111 to the terminal part 114, may, for example, be formed of a bump or a wire. The connecting unit 113 is included inside the mold part 112, wherein one side of the connecting unit 113 may be connected to the chip 111 and the other side thereof may be connected to the terminal part 114.

Further, the chips 111 may, for example, use a semiconductor device, an active device or a passive device, etc., and may be bonded by both a wire bonding and a flip-chip bonding according to the connection unit 113.

Meanwhile, the chip 111 is not mounted directly on the buildup layer 120 of the package substrate 100a but is surrounded by the mold part 112 to be included in the base part 110, making it possible to be safe from the external force, to be protected from stress during the buildup process, and to be conveniently replaced.

The buildup layer 120, which is a member formed on the base part 110, including the side surfaces of the base part 110, may include an insulating layer 121 and a circuit layer 122.

Herein, the insulating layer 121 is formed, including the side surfaces of the base part 110, and is formed on one surface of the base part 110 on which the terminal part 114 is formed. Moreover, the insulating layer 121 may, for example, be made of polyimide. In this case, the insulating layers of each layer of the buildup layer 120 may have different glass transition temperature and apply different temperature to each layer when replacing the base part 110, thereby facilitating the replacement of the base part 110.

The circuit layer 122 is made of conductive metals, wherein one outermost circuit layer 122a may be connected to the terminal part 114 and the other outermost circuit layer 122b may be connected to an external device (not shown) through a separate solder ball 130. Herein, when the solder ball 130 is formed, it is preferable that a surface treatment layer 131 is formed on the other outermost circuit layer 122b by electrolytic or electroless Tin plating, OSP treatment, HASL treatment, etc. Meanwhile, FIG. 3 illustrates the case where the circuit layers 122 of each layer are interconnected, which is provided by way of example only. A via (not shown) that connects the circuit layers 122 of the buildup layer 120 may further be included.

In addition, although the buildup layer 120 is constituted by two layers in FIG. 3, it may be constituted by a single layer or a multi-layer.

The base substrate 140 is formed on the other side of the base part 110 on which the terminal part 114 is not formed.

Herein, the base substrate 140, which is a member for heat-radiating the chip 111, is preferably made of materials having large thermal conductivity. The base substrate 140 may, for example, be formed of a metal substrate such as copper, aluminum and SUS, or an anodizing substrate including an anodic oxide layer.

Meanwhile, when the base substrate 140 is formed, an adhesive layer 141 may be formed between the base substrate 140 and the base part 110, At this time, the adhesive layer 141 may serve to fix both the base substrate 140 and the base part 110.

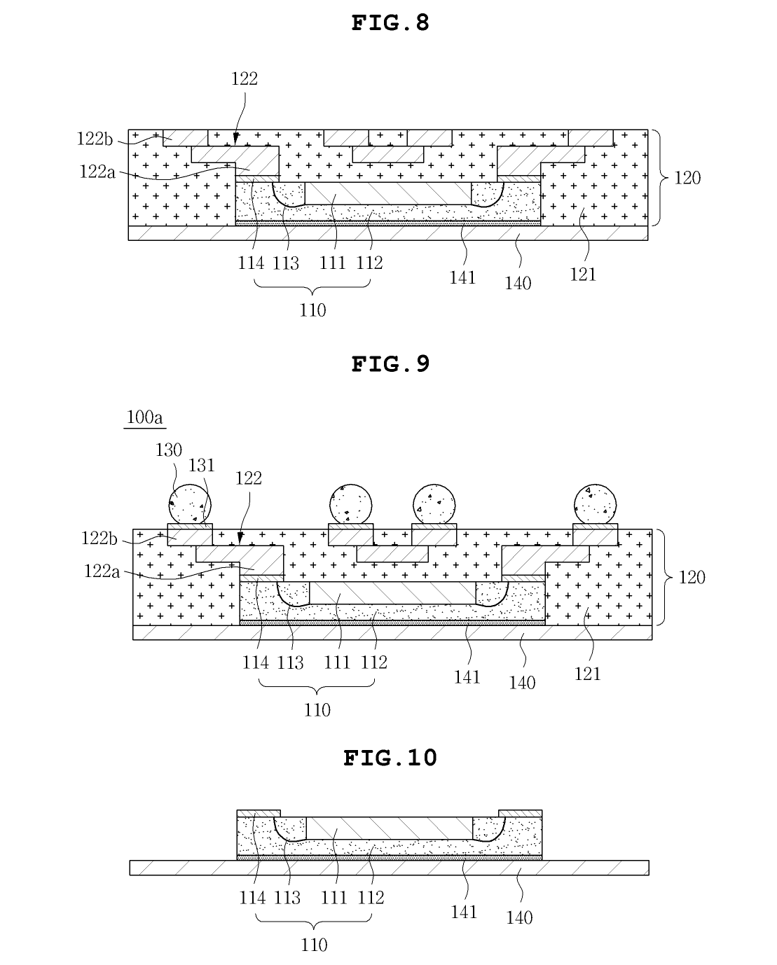

FIG. 4 is a cross-sectional view of a package substrate 100b according to a preferred second embodiment of the present invention. Hereinafter, the package substrate 100b according to the second embodiment will be described with reference to FIG. 4. Herein, the identical or corresponding constituents will use the same reference numerals and the overlapped description with the first embodiment will be omitted.

As shown in FIG. 4, the package substrate 100b according to the second embodiment includes a base part 110, a buildup layer 120 formed on one surface of the base part 110, including the side surfaces of the base part 110, and a base substrate 140 formed on the other surface of the base part 110, but further includes a radiation fin 142 that penetrates through the base substrate 140.

The radiation fin 142 penetrates through the base substrate 140, wherein one side thereof is connected to the base part 110 and the other side thereof is exposed to the outside of the base substrate 140.

Herein, the radiation fin 142 may be formed of metal having large thermal conductivity such as the base substrate 140 and the radiation fin 142 may be formed in plural on the base substrate 140, wherein the radiation fins 142 are spaced from each other. Further, the heat generated from the chip 111 is more efficiently discharged to the outside by the radiation fin 142. Meanwhile, when an adhesive layer 141 is formed between the base substrate 140 and the base part 110, the radiation fin 142 is formed by penetrating through the base substrate 140 and the adhesive layer 141.

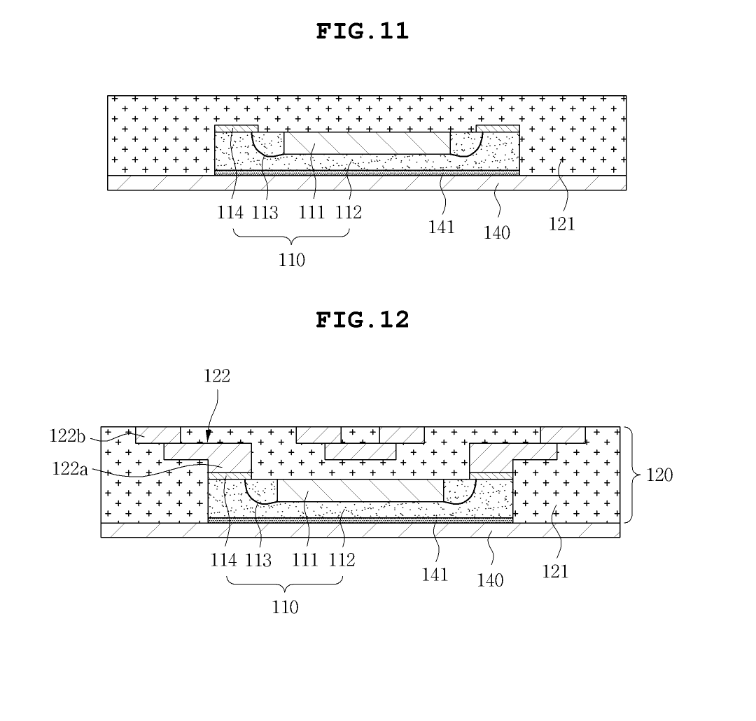

FIG. 5 is a cross-sectional view of a package substrate 100c according to a preferred third embodiment of the present invention. Hereinafter, the package substrate 100c according to the third embodiment will be described with reference to FIG. 5. Herein, the identical or corresponding constituents will use the same reference numerals and the overlapped description with the first embodiment and the second embodiment will be omitted.

As shown in FIG. 5, the package substrate 100c according to the third embodiment includes a base part 110, a buildup layer 120 formed on one surface of the base part 110, including the side surfaces of the base part 110, and a base substrate 140 formed on the other surface of the base part 110, wherein the base part 110 is positioned in an open part 144 of the base substrate 140.

The open part 144 is formed in the base substrate 140 and the base part 110 is positioned in the open part 144 so that the other surface of the base part 110 is exposed to the outside.

Herein, the exposed surface of the base part 110 may be the same plane as the surface exposed to the outside of the base substrate 140. Moreover, a separate adhesive layer may be formed on an interface surface 145 between the base part 110 and the base substrate 140 or the insulating layer 121 of the buildup layer 120 may be depressed thereon.

Meanwhile, differently from the first embodiment and the second embodiment, the base part 110 is exposed directly to the outside so that heat radiation effect is more improved, thereby reducing the case where the chip 111 is malfunctioned by high heat.

<Method of Fabricating Package Substrate>

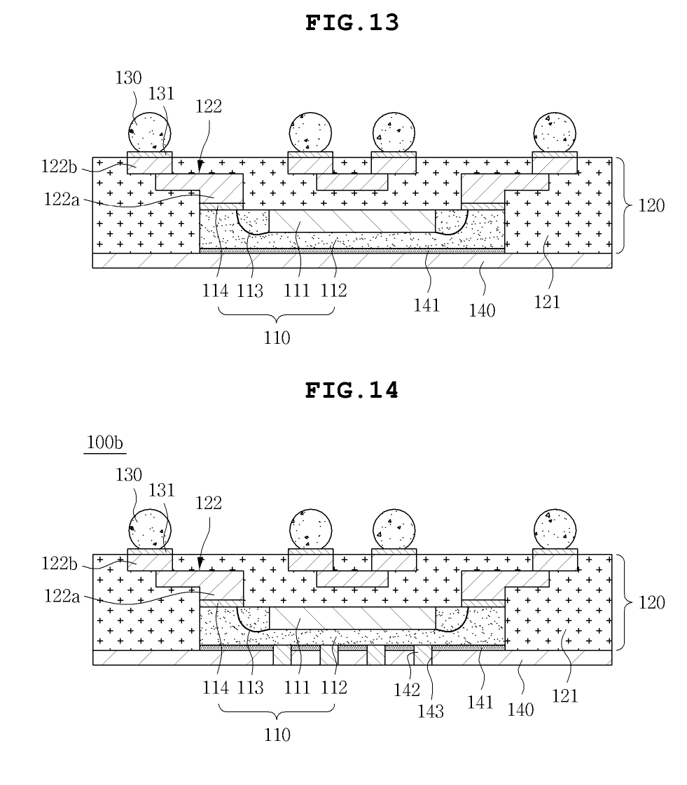

FIGS. 6 to 9 are process cross-sectional views explaining a method of fabricating a package substrate 100a according to a preferred first embodiment of the present invention. Hereinafter, the method of fabricating the package substrate 100a according to the first embodiment will be described with reference to FIGS. 6 to 9.

First, as shown in FIG. 6, the base part 110 is positioned on the base substrate 140.

At this time, the connection unit 113 is connected to the chip 111, the mold part 112 is formed to surround the outer surface of the chip 111, and the terminal part 114 connected to the connection unit 113 is formed on the outer surface of the mold part 112, thereby making it possible to prepare the base part 110. Although FIG. 6 illustrates a wire as the connection unit 113, this is provided by way of example only. Therefore, the connection unit may also be formed of a bump or another connection unit.

Moreover, when positioning the base part 110 on the base substrate 140, the adhesive layer 141 may be interposed between the base part 110 and the base substrate 140 in order to improve the fixing force therebetween.

Then, as shown in FIG. 7, the insulating layer 121 is formed on the base substrate 140 on which the base part 110 is formed.

Herein, the insulating layer 121 is formed, including the side surfaces of the base part 110, wherein it may be formed to cover the upper surface of the base part 110. Further, the insulating layer 121 may, for example, be made of polyimide.

Meanwhile, since the chip 111 is protected by the mold part 112 of the base part 110, the chip 111 is subjected to relatively small stress even though the insulating layer 121 is stacked thereon and thus, the chip 111 can be stably maintained.

Then, as shown in FIG. 8, the buildup layer 120 is formed by repeatedly forming the circuit layer 122 on the insulating layer 121.

At this time, a trench is formed in the insulating layer 121 and a plating process is performed on the trench, thereby making it possible to form the circuit layer 122, Moreover, the trench may, for example, be formed by a laser method using excimer laser or an imprint method. However, the method of forming the circuit layer 122 is not limited to the trench method but may also use a subtractive process, a full additive process, a semi-additive process, etc.

After forming the circuit layer 122, a process of stacking the insulating layer 121 is repeated again, thereby forming the buildup layer 120. Moreover, one outermost circuit layer 122a of the circuit layer 122 may be connected electrically to the terminal part 114 of the base part 110. Meanwhile, although the buildup layer 120 is constituted by two layers in FIG. 8, it may also be constituted by a single layer or a multi-layer and the respective circuit layers 122 may be connected through a via (not shown).

Then, as shown in FIG. 9, the surface treatment layer 131 may be formed on the other outermost circuit layer 122b of the buildup layer 120 and the solder ball 130 may be formed on the surface treatment layer 131.

The package substrate 100a according to the preferred first embodiment as shown in FIG. 9 is fabricated through the fabrication process as described above.

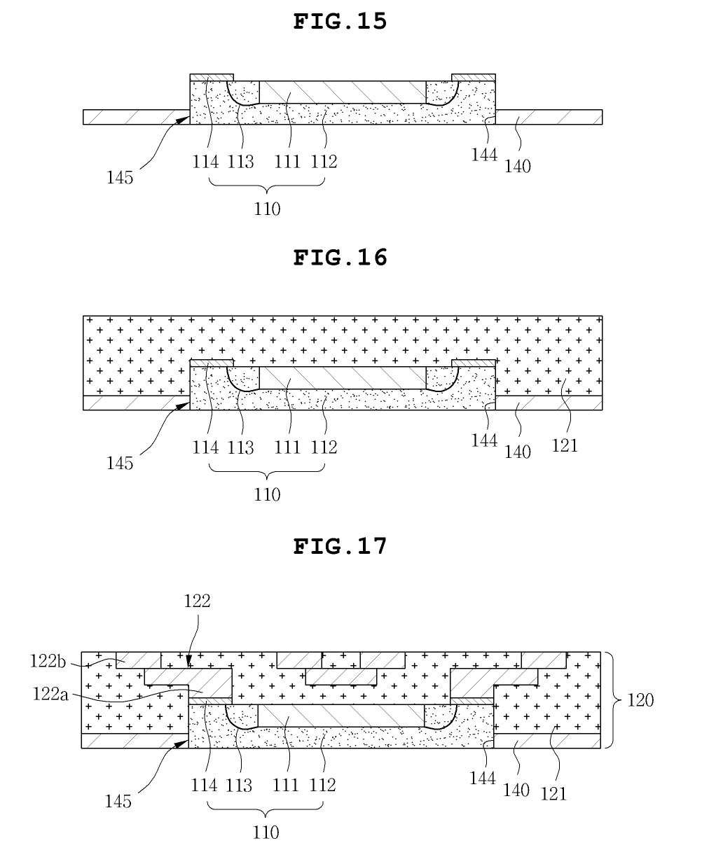

FIGS. 10 to 14 are process cross-sectional views explaining a method of fabricating a package substrate 100b according to a preferred second embodiment of the present invention. Hereinafter, the method of fabricating the package substrate 100b according to this embodiment will be described with reference to FIGS. 10 to 14. Herein, the identical or corresponding constituents will use the same reference numerals and the overlapped description with the first embodiment will be omitted.

First, as shown in FIGS. 10 to 13, the base part 110 is positioned on the base substrate 140, the buildup layer 120 is stacked by forming the insulating layer 121 and forming the circuit layer 122 on the base substrate 140, including the side surfaces of the base part 110, and the surface treatment layer 131 and the solder ball 130 are formed on the other outermost circuit layer 122b of the buildup layer 120.

Then, as shown in FIG. 14, the radiation fin 142 is formed by penetrating through the base substrate 140.

At this time, a hole 143 may, for example, be processed in the base substrate 140 using a process drill and the radiation fin 142 may be inserted into the hole 143. One side of the radiation fin 142 may be connected to the base part 110 by penetrating through the base substrate 140 and the other side of the radiation fin 142 may be exposed to the outside Further, when the adhesive layer 141 is formed, the hole 143 is formed in both the base substrate 140 and the adhesive layer 141 so that the radiation fin 142 can penetrate through both the base substrate 140 and the adhesive layer 141. Meanwhile, as the radiation fin 142 is formed, the heat generated from the chip 111 can be more rapidly discharged to the outside.

The package substrate 100b according to the preferred second embodiment as shown in FIG. 14 is fabricated through the fabrication process as described above.

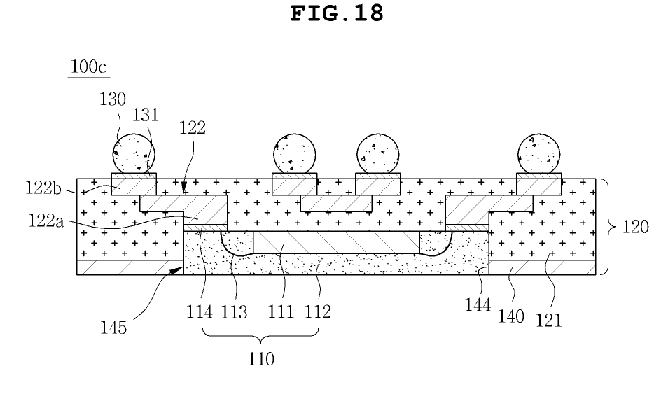

FIGS. 15 to 18 are process cross-sectional views explaining a method of fabricating a package substrate 100c according to a preferred third embodiment of the present invention. Hereinafter, the method of fabricating the package substrate 100c according to this embodiment will be described with reference to FIGS. 15 to 18. Herein, the identical or corresponding constituents will use the same reference numerals and the overlapped description with the first embodiment and the second embodiment will be omitted.

First, as shown in FIG. 15, the open part 144 is formed in the base substrate 140 and the base part 110 is positioned in the open part 144.

At this time, the open part 144 may, for example, be formed in the base substrate 140 using a process drill method or a laser method. Moreover, the exposed surface of the base part 110 may correspond to the exposed surface of the base substrate 140 by forming the open part 144 to be equal to or slightly larger than the size of the base part 110. Meanwhile, a separate sheet (not shown) may further be formed on the lower portions of the base substrate 140 and the base part 110 in order to fix the base substrate 140 to the base part 110. Alternately, the base part 110 and the base substrate 140 may be mutually fixed by interposing adhesive therebetween.

Then, as shown in FIG. 16, the insulating layer 121 is formed on the base part 110 and the base substrate 140.

At this time, the insulating layer 121 is depressed between the base part 110 and the base substrate 140, thereby making it possible to interconnect the base part 110 and the base substrate 140. Meanwhile, the base part 110 is formed in the open part 144 of the base substrate 140 to be exposed to the outside, thereby making it possible to more improve heat radiation effect.

Then, as shown in FIGS. 17 and 18, the buildup layer 120 is formed by forming the circuit layer 122 on the insulating layer 121, and the surface treatment layer 131 and the solder ball 130 are formed on the other outermost circuit layer 122b.

The package substrate 100c according to the preferred third embodiment as shown in FIG. 18 is fabricated through the fabrication process as described above.

The package substrate and the method of fabricating the same according to the present invention forms the base part that protects the chip, making it possible to reduce stress applied to the chip even though the buildup process is processed on the base part.

Further, with the present invention, although defects occur in the chip, it can be solved only by replacing the base part, making it possible to facilitate the replacement of the chip.

Further, with the present invention, the base substrate is formed on the lower portion of the base part, having an excellent heat radiation effect.

Further, with the present invention, the radiation fin is inserted into the base substrate or the open part is formed in the base substrate, making it possible to more improve the heat radiation effect.

Further, with the present invention, polyimide having different glass transition temperature is used as the insulation layer of the buildup layer, making it possible to facilitate the replacement of the base part.

Although the preferred embodiments of the present invention have been disclosed for illustrative purposes, they are for specifically explaining the present invention and thus the package substrate and the method of fabricating the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A package substrate, comprising:
a base part that includes a chip, a mold part surrounding the chip, and a connection unit formed inside the mold part to connect the chip to a terminal part formed on the outer surface of the mold part; and
a buildup layer that is formed on one surface of the base part on which the terminal part is formed, including the side surfaces of the base part, includes a circuit layer connected to the terminal part.

2. The package substrate as set forth in claim 1, further comprising:
a base substrate formed on the other surface of the base part.

3. The package substrate as set forth in claim 1, further comprising:
a solder ball connected to the outermost circuit layer of the circuit layers of the buildup layer.

4. The package substrate as set forth in claim 2, further comprising:
an adhesive layer formed between the base part and the base substrate.

5. The package substrate as set forth in claim 1, wherein the buildup layer includes insulating layers made of polyimide.

6. The package substrate as set forth in claim 5, wherein the insulating layers of each layer of the buildup layer have different glass transition temperature.

7. The package substrate as set forth in claim 2, wherein the base substrate is a metal substrate or an anodizing substrate.

8. The package substrate as set forth in claim 1, wherein the connection unit is a bump or a wire.

9. The package substrate as set forth in claim 2, further comprising:
a radiation fin of which one side is connected to the base part and the other side is exposed to the base substrate.

10. The package substrate as set forth in claim 2, further comprising:
an open part formed in the base substrate, wherein the base part is exposed to the outside through the open part.

11. The package substrate as set forth in claim 10, wherein the exposed surface of the base part and the surface of the base substrate exposed to the outside have the same plane.

12. A method of fabricating a package substrate, comprising:
(A) positioning a base part that includes a chip, a mold part surrounding the chip, and a connection unit formed inside the mold part to connect the chip to a terminal part formed on the outer surface of the mold part, on a base substrate; and
(B) stacking a buildup layer by forming an insulating layer on the base substrate, including the side surfaces of the base part, and forming a circuit layer connected to the terminal part.

13. The method of fabricating the package substrate as set forth in claim 12, further comprising:
(C) forming a solder ball that is connected to an outermost circuit layer of the circuit layers of the buildup layer.

14. The method of fabricating the package substrate as set forth in claim 12, wherein at step (A), when the base part is positioned on the base substrate, an adhesive layer is interposed between the base part and the base substrate.

15. The method of fabricating the package substrate as set forth in claim 12, wherein at step (A), the base substrate is a metal substrate or an anodizing substrate.

16. The method of fabricating the package substrate as set forth in claim 12, wherein at step (B), the insulating layer of the buildup layer is made of polyimide.

17. The method of fabricating the package substrate as set forth in claim 12, wherein at step (B), the insulating layers of each layer of the buildup layer have different glass transition temperature.

18. The method of fabricating the package substrate as set forth in claim 12, wherein at step (A), the connection unit is a bump or a wire.

19. The method of fabricating the package substrate as set forth in claim 12, further comprising:
(C) forming a radiation fin that connects the base part to the outside of the base substrate by penetrating through the base substrate.

20. The method of fabricating the package substrate as set forth in claim 12, wherein the step (A) includes:
(A1) preparing a base part by forming a connection unit connected to the chip, a mold part surrounding the chip, and a terminal part connected to the connection unit on the outer surface of the mold part;
(A2) forming an open part in a base substrate; and
(A3) positioning the base part in the open part.
